(19) United States
(12) Patent Application Publication
(10) Pub. No.: US 2016/0307849 A1
(43) Pub. Date: Oct. 20, 2016

(54) Semiconductor Device and Manufacturing Method

(71) Applicant: Infineon Technologies AG, Neubiberg (DE)

(72) Inventors: Thorsten Meyer, Muenchen (DE); Stephan Senn, Munchen (DE)

(21) Appl. No.: 15/095,650

(22) Filed: Apr. 11, 2016

(30) Foreign Application Priority Data
Apr. 15, 2015 (DE) 102015105758.1

(51) Int. Cl. H01L 23/532; H01L 29/78; H01L 29/66; H01L 21/768; H01L 21/8234; H01L 27/088; H01L 29/40

(52) U.S. Cl. CPC H01L 23/53271; H01L 23/53257; H01L 27/088; H01L 29/7801; H01L 29/407; H01L 21/76877; H01L 21/76831; H01L 21/823475; H01L 29/66674

(57) ABSTRACT

The present disclosure relates to a semiconductor device, comprising a semiconductor substrate; a trench extending into the semiconductor substrate, wherein the trench is partly filled with an electrically conductive structure insulated from the semiconductor substrate; a polysilicon or amorphous silicon routing structure laterally bridging the trench; and an insulation layer between the trench and the routing structure.

### FIELD

Embodiments generally relate to semiconductor devices and methods for manufacturing semiconductor devices, and, more particularly, to electrical routing within such semiconductor devices.

### BACKGROUND

Integrated Circuits (ICs) typically include multiple regions of electronic circuits implemented on one plate or substrate of semiconductor material, for example, silicon. Such semiconductor devices often make use of trench structures formed into the semiconductor substrate. Trench structures can be used for various purposes, such as for controlling a course of electrical potentials within an IC or for providing gate structures for transistors, for example. In such cases a trench may comprise one or more electrically conductive structures, for example made of polysilicon, and insulated by oxide layers from the semiconductor substrate and other electrically conductive structures such as metal layers, for example. Metal or polysilicon structures arranged on top of the semiconductor substrate may be used for electrical routing between different circuit components integrated in the semiconductor substrate. In power-ICs such different circuit components or regions may be a power transistor cell array one the one hand and, on the other hand, one or more related logic circuits for controlling the power transistor cell array or individual transistor cells thereof.

In particular with regard to cost-driven semiconductor manufacturing technologies using only a little number of metal layers, electrical routing capabilities are limited.

### SUMMARY

Hence, one object of embodiments is to improve electrical routing capabilities in semiconductor devices.

An embodiment of the present disclosure relates to a semiconductor device. The semiconductor device includes a semiconductor substrate and a trench extending into the semiconductor substrate. The trench is partly filled with an electrically conductive structure insulated from the semiconductor substrate. The semiconductor device further includes a routing structure of polysilicon or amorphous silicon laterally bridging the trench, and an insulation layer between the trench and the routing structure.

In some embodiments, the trench may surround a first integrated circuit region comprising one or more integrated circuit components. The routing structure electrically connects at least one integrated circuit component of the first integrated circuit region to at least one integrated circuit component of a second integrated circuit region outside the trench and the first integrated circuit region.

In some embodiments, the first integrated circuit region may comprise a region of the semiconductor substrate forming an insulated well around the one or more integrated circuit components.

In some embodiments, the second integrated circuit region may comprise a cell array of a semiconductor power device. The cell array may include a plurality of transistor cells.

In some embodiments, the at least one integrated circuit component of the first integrated circuit region may be configured to control at least one gate terminal of a transistor cell of the cell array.

In some embodiments, the trench's electrically conductive structure comprises a field plate.

In some embodiments, the semiconductor power device may be a Double-Diffused MOS, DMOS, device.

In some embodiments, the insulation layer may have a breakdown voltage of at least 5 Volts between the trench's electrically conductive structure and the routing structure of polysilicon or amorphous silicon.

In some embodiments, the electrical isolation layer may have a thickness of at least 30 nm between the trench's electrically conductive structure and the routing structure of polysilicon or amorphous silicon.

In some embodiments, the trench's electrically conductive structure may comprise polysilicon, amorphous silicon or tungsten.

In some embodiments, the semiconductor device contains at most two metal layers.

According to a further aspect, the present disclosure provides a method for manufacturing a semiconductor device. The method includes an act of forming a trench extending into a semiconductor substrate, an act of partly filling the trench with an electrically conductive structure and insulating the electrically conductive structure from the semiconductor substrate. The method further includes forming an insulation layer covering the trench's electrically conductive structure, and forming, on the insulation layer, a routing structure of polysilicon or amorphous silicon laterally extending over the trench.

In some embodiments, the method may further include forming the trench to surround a first region of the semiconductor substrate, forming one or more first integrated circuit components into the first region, forming one or more second integrated circuit components into a second region on an opposite side of the trench, and forming the routing structure to electrically connect at least one of the first integrated circuit components to at least one of the second integrated circuit components.

In some embodiments, the process of forming the trench surrounding the first region may include forming at least one further trench in or surrounding the second region of the semiconductor substrate. That is, the trench surrounding the first region and the at least one further trench of the second region may be formed during the same process step.

In some embodiments, the process of forming the routing structure may include forming at least one further polysilicon or amorphous silicon structure within the first and/or the second region of the semiconductor substrate.

In some embodiments, forming the one or more second integrated circuit components in the second region may include forming a cell array of a semiconductor power device.

In some embodiments, forming the one or more first integrated circuit components in the first region may include forming a control logic circuit for the cell array.

In some embodiments, providing the insulation layer may include locally oxidizing the trench's electrically conductive structure in an upper portion of the trench.

In some embodiments, forming the trench may include forming the electrically conductive structure using polysilicon, amorphous silicon or tungsten.

In some embodiments, the method may further include forming at most two metal layers above the polysilicon structure, for example one signal metal layer and one top power metal layer.

### BRIEF DESCRIPTION OF THE FIGURES

Some embodiments of apparatuses and/or methods will be described in the following by way of example only, and with reference to the accompanying figures, in which

FIG. 1a illustrates a schematic cross-sectional view of a semiconductor device according to an embodiment;

FIG. 1b illustrates a schematic flow-chart of a method for manufacturing a semiconductor device according to an embodiment;

FIG. 2 illustrates a more detailed cross-sectional view of a semiconductor device according to a further embodiment;

FIG. 3 illustrates a magnified cross-sectional view of a semiconductor device according to a further embodiment; and

FIG. 4 shows top views of a conventional and a proposed routing concept.

### DETAILED DESCRIPTION

Various example embodiments will now be described more fully with reference to the accompanying drawings in which some example embodiments are illustrated. In the figures, the thicknesses of lines, layers and/or regions may be exaggerated for clarity.

Accordingly, while further embodiments are capable of various modifications and alternative forms, some example embodiments thereof are shown by way of example in the figures and will herein be described in detail. It should be understood, however, that there is no intent to limit example embodiments to the particular forms disclosed, but on the contrary, example embodiments are to cover all modifications, equivalents, and alternatives falling within the scope of the disclosure. Like numbers refer to like or similar elements throughout the description of the figures.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of further example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art, unless expressly defined otherwise herein.

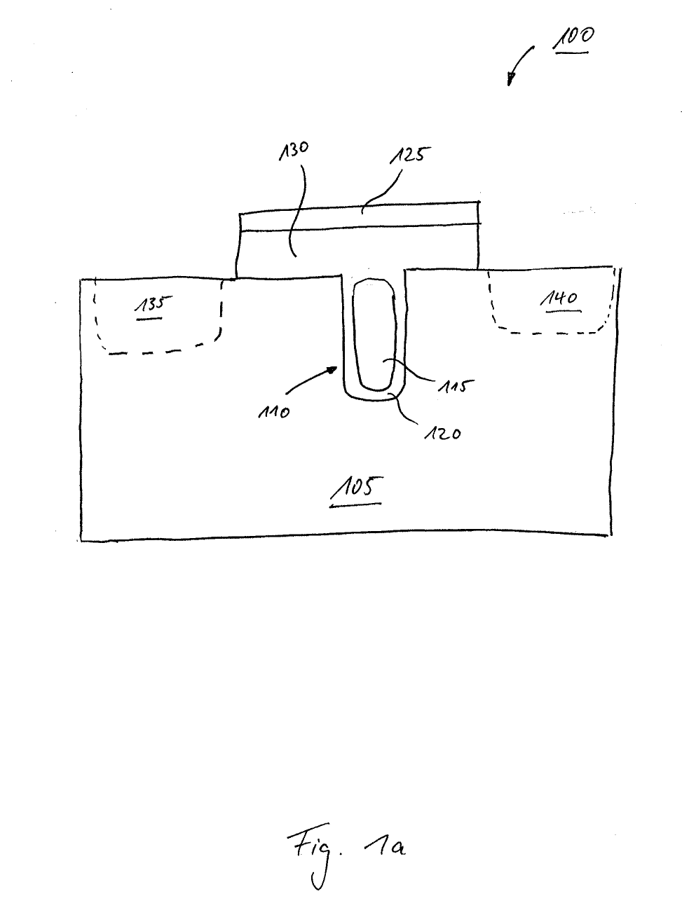

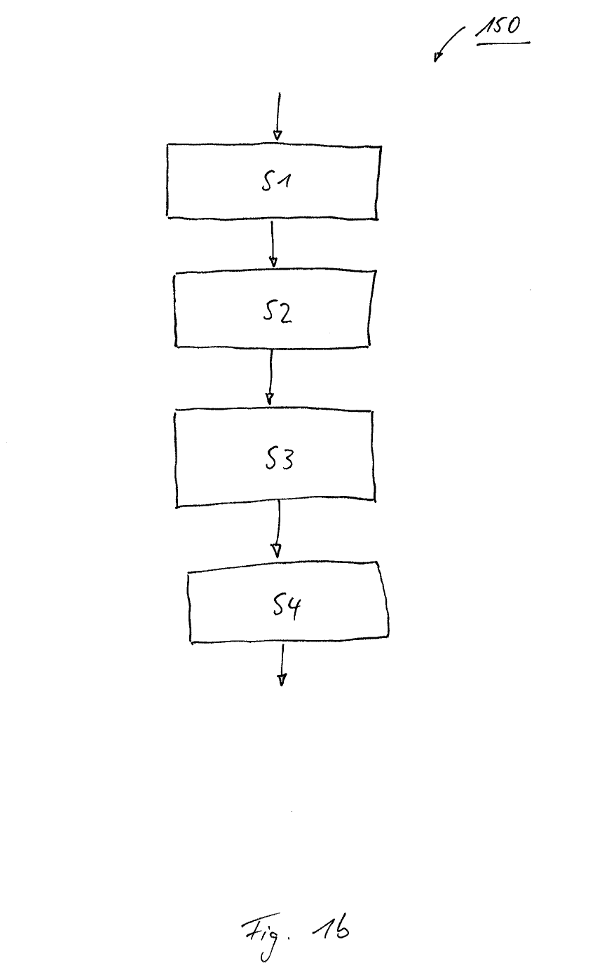

Turning now to FIG. 1a, it is illustrated a schematic cross-sectional view of a semiconductor device 100 according to an embodiment.

The semiconductor device 100 comprises a semiconductor substrate or body 105. As will be explained in more detail below, the semiconductor substrate 105 may include differently doped regions of any suitable semiconductor material, such as silicon (Si), for example. In the illustrated embodiment a trench 110 vertically extends from a main surface into the semiconductor substrate 105. Thereby a main surface of the semiconductor structure may be a surface of the semiconductor structure towards metal layers, insulation layers or passivation layers on top of the semiconductor structure. In comparison to a substantially vertical edge (e.g. resulting from separating the semiconductor dies from others) of the semiconductor structure, the main surface of the semiconductor structure may be a substantially horizontal surface. The main surface of the semiconductor structure may be a substantially even plane (e.g. neglecting unevenness of the semi-conductor structure due to the manufacturing process). In other words, the main surface of the semiconductor structure may be the interface between the semiconductor material and an insulation layer, metal layer or passivation layer on top of the substrate 105.

The trench 110 comprises an electrically conductive structure 115 which is insulated from the surrounding semiconductor substrate 105. For example, the electrically conductive structure 115 may comprise tungsten, polysilicon and/or amorphous silicon. The insulation of the electrically conductive structure 115 can be obtained by various well-known means, such as, for example, a Field OXide (FOX) layer 120 surrounding the electrically conductive structure 115. One possible example for FOX would be a layer 120 of SiO₂.

The semiconductor device 100 comprises a routing structure 125 of polysilicon or amorphous silicon. This routing structure 125 laterally bridges the trench 110 and may be a substantially planar routing structure on top of the semiconductor substrate's main surface and underneath an optional metal layer (not shown). An insulation layer or structure 130 is deposited between the trench 110 and the routing structure 125 laterally extending over the trench 110. For example, the insulation layer 130 may be implemented by depositing an oxide of semiconductor material.

According to a further aspect, embodiments also provide a method 150 for manufacturing the semiconductor device 100. A flow chart of the manufacturing method 150 is illustrated in FIG. 1b.

Method 150 includes an act S1 of forming the trench 110 extending into the semiconductor substrate 105. During an act S2 the trench 110 is partly filled with the electrically conductive structure 115 which is insulated from the semiconductor substrate 105 by forming the insulation layer 120 (e.g. a FOX layer) prior to filling the trench 110 with the electrically conductive structure 115. Method 150 further includes an act S3 of forming the insulation layer 130 covering the trench's electrically conductive structure 115, and an act S4 of forming, on the insulation layer 130, the routing structure 125 of polysilicon or amorphous silicon laterally extending over the trench 110.

The person skilled in the art will appreciate that the acts of method 150 for manufacturing the semiconductor device 100 may be performed by conventional semiconductor patterning processes including photolithography, for example.

In some embodiments, the semiconductor device 100 may be a so-called power semiconductor device (power IC) for handling higher power levels occurring in applications such as automotive, transportation, industrial, lighting and motor control, for example. In other words, a semiconductor device according to the described concept may have a blocking voltage of more than 20 V (e.g. between 20 V and 10000 V or more than 100 V, more than 500 V or more than 1000 V). Hence, the semiconductor device 100 may include power Metal Oxide Semiconductor Field-Effect Transistors (MOSFETs), such as Double-Diffused MOS (DMOS) FETs, for example.

Now turning back to FIG. 1a, the polysilicon or amorphous silicon routing structure 125 above the trench 110 is electrically conductive and may hence be used, besides one or more optional metal layers or structures (not shown), for electrical routing within the semiconductor device 100. For driving power MOSFETs via the routing structure 125, for example, the insulation layer 130 may have a breakdown voltage of at least 5 Volts between the trench's 110 electrically conductive structure 115 and the routing structure 125. In other embodiments the insulation layer's 130 breakdown voltage may be even higher, for example at least 10, at least 20 or at least 30 Volts. To obtain high enough breakdown voltages between the trench's 110 electrically conductive structure 115 and the routing structure 125, the electrical isolation layer 130 may, in some embodiments, have a thickness of at least 30 nm between the trench's electrically conductive structure 115 and the polysilicon structure 125. In other embodiments the insulation layer's 130 thickness may be higher, for example at least 50 nm, at least 100 nm or at least 150 nm. This may depend on the employed semiconductor process technology.

In FIG. 1a the broken lines indicate an optional first integrated circuit region 135 comprising one or more integrated circuit components and, on the opposite side of the trench 110 (here: right), an optional second integrated circuit region 140 comprising one or more integrated circuit components. The first and second integrated circuit regions 130, 140 may be embedded in respective wells formed into the semiconductor substrate. The polysilicon or amorphous silicon routing structure 125 may electrically connect at least one integrated circuit component of the first integrated circuit region 135 to at least one integrated circuit component of the second integrated circuit region 140 of the semiconductor device 100.

In some embodiments, the trench 110 may be formed to surround or circumscribe the first integrated circuit region 135, leading to an annular-like trench 110. Here, the second integrated circuit region 140 may be located in an area outside an area surrounded by the annular trench 110, while the first integrated circuit region 135 is located in an area surrounded by the trench 110. The polysilicon or amorphous silicon routing structure 125 bridges the trench 110 to electrically connect the first integrated circuit region 135 circumscribed by the trench 110 to the second integrated circuit region 140 outside the trench 110.

In some embodiments, the second integrated circuit region 140 may be a power transistor cell or a power transistor cell array. Thereby a cell array forming a power transistor comprises a plurality of individual transistor cells which are typically connected in parallel. The power transistor of the second integrated circuit region 140 may use a vertical diffused MOSFET structure in some embodiments. At least one integrated circuit component of the first integrated circuit region 135 may be configured to control at least one gate terminal of a transistor cell of the cell array in region 140. In other words, the first integrated circuit region 135 may comprise control circuitry for driving a power transistor of the second region 140. In some embodiments, the first integrated circuit region 135 may hence be a logic cell formed at an edge of region 140 with the transistor cell array.

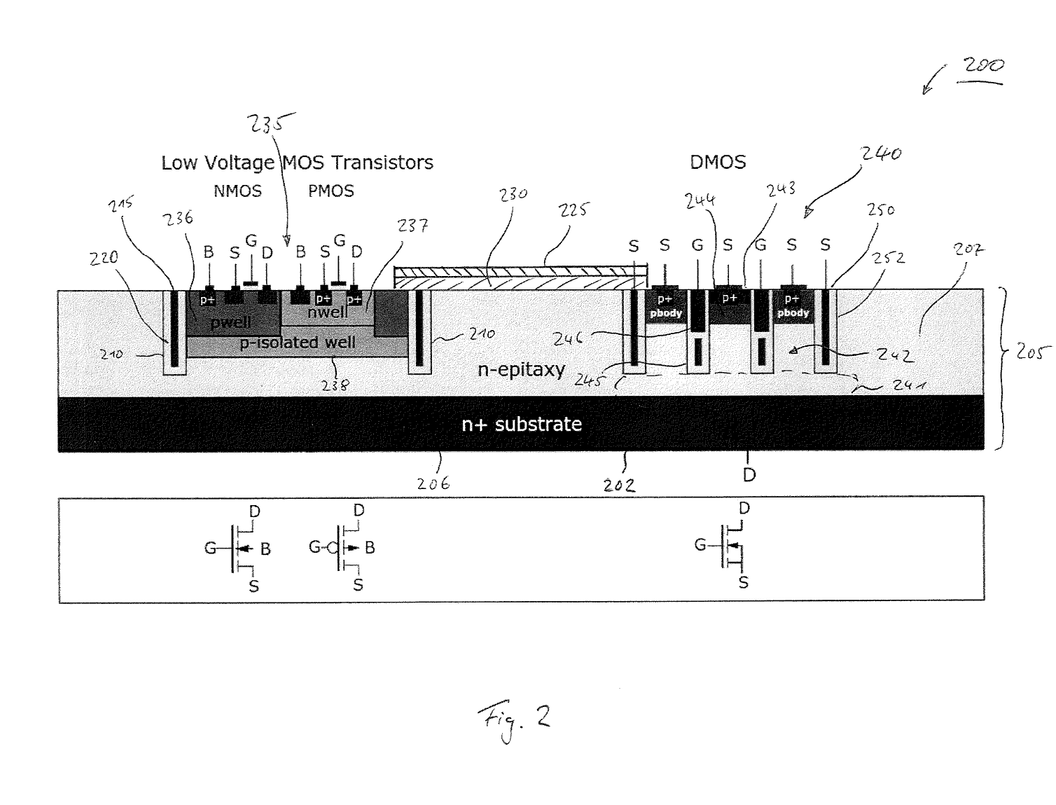

FIG. 2 illustrates a schematic cross-sectional view of a semiconductor device 200 according to an example embodiment with a DMOS power transistor implemented in a second integrated circuit region 240 and a related control logic implemented in a first integrated circuit region 235.

The semiconductor device 200 comprises a semiconductor body 205 including a heavily doped substrate portion 206 of a first conductivity type on top of a metal layer 202 forming a drain contact for the DMOS power transistor of the second integrated circuit region 240. In the illustrated example the heavily doped substrate portion 206 is of n+-type conductivity (e.g. caused by incorporating nitrogen ions, phosphor ions or arsenic ions). An epitaxial layer 207 of the first conductivity type is formed on top of the heavily doped substrate portion 206. The thickness and doping of the epitaxial layer 207 typically determines a voltage rating of the semiconductor device 200. From a top surface formed into the epitaxial layer 207 there are formed the first and the second integrated circuit regions 235 and 240.

The control logic implemented in the first integrated circuit region 235 schematically comprises a first and a second lateral transistor. For example, the first and second lateral transistors are transistors of different channel types, e.g. NMOS and PMOS transistors. While source and drain regions of the first lateral transistor (e.g. NMOS FET) are highly doped substrate portions of the first conductivity type (e.g. n-type) formed in a common well 236 of the second conductivity type (e.g. p-type by incorporating aluminum ions or boron ions), the source and drain regions of the second lateral transistor (e.g. PMOS FET) are highly doped substrate portions of the second conductivity type (e.g. p-type) formed in a common well 237 of the first conductivity type (e.g. n-type). Well 237 is isolated against epitaxial layer 207 by means of a well 238 of the second conductivity type (e.g. p-type).

The example DMOS power transistor implemented in the second integrated circuit region 240 comprises a number of identically formed transistor cells. A region 241 in the epitaxial layer 207 and/or the heavily doped substrate portion 206 above metal layer 202 may form a connection zone 241 of the first conductivity type for the DMOS power transistor. Heavily doped zones 243 of the first conductivity type are provided in an area of the main surface of the semiconductor body 205, underneath which a zone 244 of the second conductivity type, which is complementary to the first conductivity type, is disposed.

The connection zone 241 is used as a common drain zone for all the transistor cells. The heavily doped region 243, which are disposed in the area of the main surface, of the first conductivity type form source regions. The regions 244, which are disposed underneath the source region 243, of the second conductivity type form a body zone of the transistor cells. Respective regions 242 of the first conductivity type and located between respective zones 244 and connection zone 241 may be used as respective drift zones of the transistor cells.

The common drain zone 241, the source zone 243 and the drift zone 242 may be n-doped in the case of an n-channel MOS transistor, and may be p-doped in the case of a p-channel MOS transistor. The body zone 244 may in each case be doped in a complementary manner.

Each transistor cell in region 240 has a gate electrode 246, which is disposed in a trench 245 which, starting from the main surface, extends in the vertical direction into the semiconductor body 205. The gate electrode 246 is isolated by an insulation layer from the semiconductor body 205, i.e., from the source zone 243, the body zone 244 and the drift zone 242. In the example embodiment it is formed in such a way that it tapers in the area underneath the body zone 244 in such a way that the thickness of the insulation layer in the trench 245 increases in this area. The gate electrode 246 is used in this area underneath the body zone 244 as a field plate for shielding the body zone 244 against high electrical field strengths. In the area of the body zone 244, the gate electrode 246 is used to form an electrically conductive channel between the source zone 243 and the drift zone 242 when a drive potential is applied. The drive potential may be controlled by control logic of circuit region 235.

In the example embodiment illustrated in FIG. 2, the gate electrodes 246 are used as a gate electrodes for in each case two transistor cells, which extend to the left and right from the trench 245 in a horizontal direction. By way of example, in FIG. 2, one gate electrode that is disposed in one trench 245 is shared by adjacent transistor cells. Furthermore, one body zone 244 is shared by two transistor cells, namely the body zone 244 disposed between two of the trenches 245. It should be mentioned that a structure that corresponds to a cell in the sense of this disclosure is sometimes also referred to as a half cell.

The cell array with the transistor cells is bounded by edge cells, with an edge cell having a field plate 250 which is disposed in a trench 252 that extends in the vertical direction into the semiconductor body 205, with the field plate 250 being isolated from the semiconductor body 205 by an insulation layer (e.g. FOX) in the trench 252. A thickness of the insulation layer may correspond approximately to the thickness of the insulation layer (e.g. FOX) around the field plate section of the gate electrodes 246 in the lower area of the trenches 245. Similar to trench 210 associated with first integrated circuit region 235, the trench 252 associated with second integrated circuit region 240 together with the field plate 250 may surround the cell array of the second integrated circuit region 240 in an annular shape, with the field plate 252 being short-circuited to the source electrodes in the illustrated example.

In embodiments, the trench(es) 210 and their fillings 215, 220 associated with the first integrated circuit region 235 may be formed together (e.g. in the same manufacturing process step) with the trenches 245, 252 and their fillings 246, 252 associated with the second integrated circuit region 240. In other words, act S1 of forming the trench 210 surrounding the first region 235 may comprise forming at least one further trench 245, 252 in the second region 240 of the semiconductor substrate 205.

To provide electrical routing between the control logic of the first integrated circuit region 235 and the cell array of the second integrated circuit region 240 a polysilicon or amorphous silicon routing structure 225 reaches from the first integrated circuit region 235 to the second integrated circuit region 240 by laterally extending over bother annular trenches 210 and 252, respectively. An insulation layer 230 is deposited between upper portions of the trenches 210, 252 and the routing structure 225 in order to insulate the routing structure 225 from the electrically conductive structures 215 and 250 in the respective trenches. As explained before, the insulation layer's 230 breakdown voltage may be adequately high, for example at least 5 Volts per 30 nm. In some embodiments, the act S2 of forming the routing structure 225 may include, in the same process step, forming at least one further polysilicon or amorphous silicon structure in the first, second or another region of the semiconductor substrate 205.

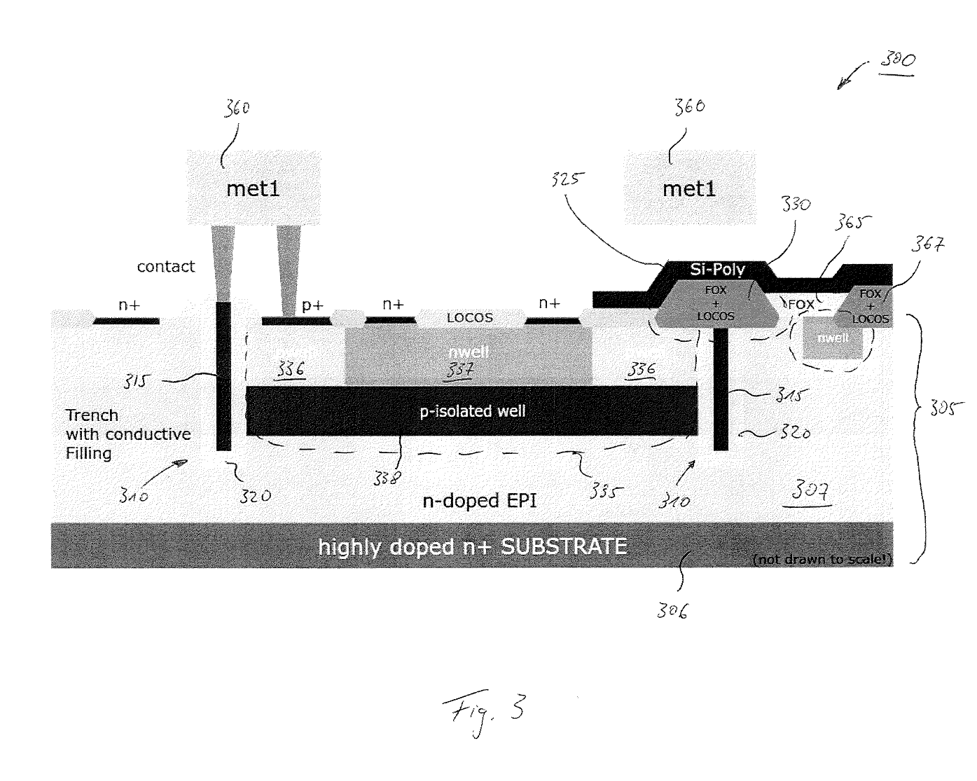

FIG. 3 illustrates a magnified cross-sectional view of a logic circuitry implemented in first integrated circuit region 335 of a semiconductor device's 300 according to an example embodiment.

Similar to FIG. 2 the semiconductor device 300 comprises a semiconductor body 305 including a heavily doped substrate portion 306 of a first conductivity type. In the illustrated example the heavily doped substrate portion 206 is of n+-type conductivity. An epitaxial layer 307 of the first conductivity type is formed on top of the heavily doped substrate portion 306. The first integrated circuit region 335 is formed in the semiconductor body 305 by forming differently doped wells 336, 337, and 338. The control circuitry implemented in region 335 is similar to the control circuitry illustrated in FIG. 2. Therefore a repetition of a description of features that have already been described with reference to FIG. 2 will be omitted for the sake of brevity.

The first integrated circuit region 335 is surrounded by trench 310 including an electrically conductive filling 315. The electrically conductive filling 315, e.g. polysilicon, amorphous silicon or tungsten, is insulated from the surrounding semiconductor substrate body 305 by means of an insulation layer 320, e.g. a semiconductor oxide. The trench's electrically conductive filling 315 functions as a field plate to protect the first integrated circuit region 335 from high voltage differences within the semiconductor body 305. The control circuitry as well as the trench's electrically conductive filling 315 are electrically contacted via a metal layer 360 used for electrical routing within the device 300.

Underneath metal layer 360 and above the trench's electrically conductive filling 315 the device 300 comprises a routing structure 325 of polysilicon or amorphous silicon. The routing structure 325 laterally bridges the trench 310 to enable electrical routing over the first integrated circuit region or isolated well block 335 with trench termination. For electrical isolation between the routing structure 325 and the trench's electrically conductive filling 315 an insulation layer 330 is deposited between the trench 310 and the routing structure 325. In particular, the insulation layer 330 may comprise an insulating oxide portion obtained by LOCal Oxidation of Silicon (LOCOS). In one embodiment, polysilicon or amorphous silicon in an upper portion of the trench's conductive filling 315 may be locally oxidized to obtain, alternatively or in addition to a Field Oxide (FOX) layer 365 deposited between the routing structure 325 and the trench 310, the insulation structure 330 of adequate thickness (>30 nm) and/or breakdown voltage >5V) between the trench's electrically conductive filling 315 and the routing structure 325. The term “LOCOS” denotes a microfabrication process where an oxide of semiconductor material, e.g. silicon dioxide (SiO₂), is formed in selected areas on a silicon wafer. For example, thermal oxidation of an upper region of the trench's polysilicon or amorphous silicon filling 315 may be used.

Without the specially deposited LOCOS insulation structure 330 above the trench's conductive filling 315 electrical routing by means of the polysilicon or amorphous silicon structure 325 would not be possible since the breakdown voltage of the relatively thin FOX layer 365 would be too small. In the area between an upper portion of the trench's electrically conductive filling 315 and the routing structure 325 the LOCOS insulation 330 provides a breakdown voltage of at least 5 Volts. This may be achieved if the LOCOS insulation 330 has a thickness of at least 30 nm given a 0.35 μm process.

As can be seen in FIG. 3, some embodiments may also comprise a channel stopper region 366 formed in the semiconductor body 305. The channel stopper region 366 is located outside the first integrated circuit region 335 circumscribed by the trench 310. In semiconductor device fabrication, a channel-stopper denoted a doped area in semiconductor devices produced by implantation or diffusion of ions, by growing or patterning the silicon oxide, or other isolation methods in semiconductor material with the primary function to limit a spread of a FET's channel area or to prevent the formation of parasitic channels (inversion layers). In the embodiment of FIG. 3 the channel stopper region 366 of the first conductivity type (here: n-type) is located under the semiconductor body's main surface below the FOX layer 365 and a further LOCOS region 367. The routing structure 325, on the other hand, extends above the FOX layer 365 and the further LOCOS region 367. Note that both LOCOS regions 330 and 367 may be fabricated in the same process step.

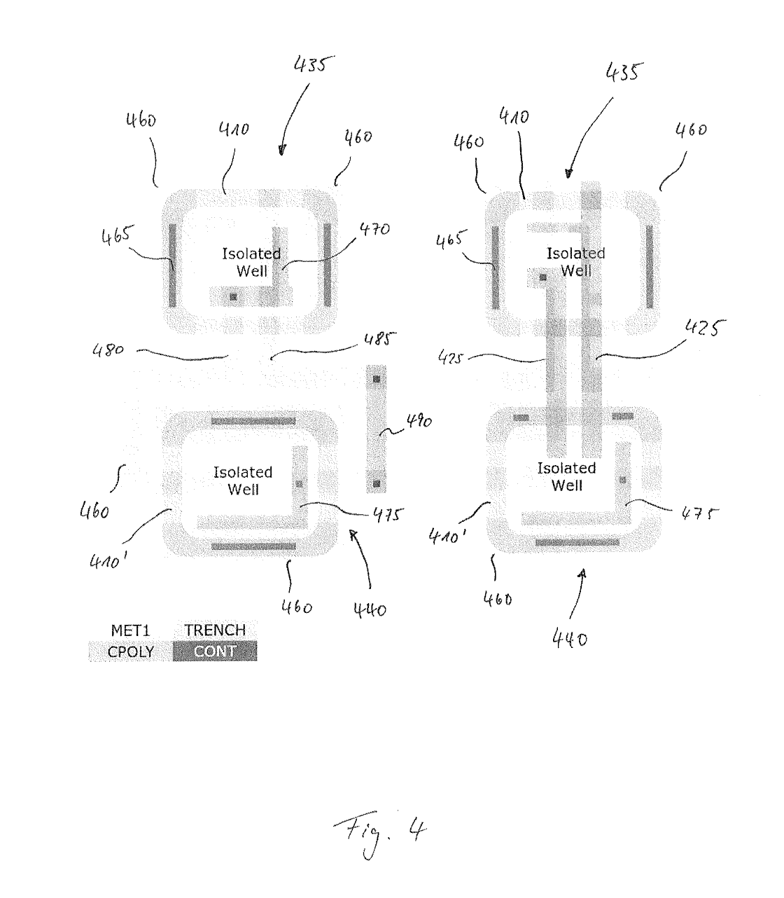

FIG. 4 shows top views of different electrical routings between adjacent circuit regions implemented in respective isolated wells. The left view of FIG. 4 shows a situation without using the routing concept of the present disclosure, while the right view of FIG. 4 shows an improved situation when using the routing concept of the present disclosure.

Both views of FIG. 4 show two integrated circuit regions 435 and 440 which are electrically connected by respective electrical routing structures. The integrated circuit regions 435 and 440 are surrounded by respective closed annular trenches 410 and 410′. The trenches 410 and 410′ are electrically contacted to a metal 1 (MET1) layer 460 by means of respective contacts or vias 465.

The conventional layout illustrated in the left half of FIG. 4 uses polysilicon structures 470, 475 for electrical routing within the integrated circuit regions 435 and 440, respectively. That is to say, the polysilicon structures 470, 475 do not extend over the trenches 410 and 410′. Electrical routing between the integrated circuit regions 435 and 440 is done by means of metal routings 480, 485 formed in metal 1 (MET1) layer 460 and a polysilicon section 490 outside the regions surrounded by the trenches 410 and 410′. Thereby the metal routings 480, 485 laterally extend over the trenches 410 and 410′.

In contrast to the conventional layout in the left portion of FIG. 4, the layout illustrated in the right half of FIG. 4 uses polysilicon routing structures 425 for electrical routing between the integrated circuit regions 435 and 440. Thereby the polysilicon routing structures 425 functionally replace the conventional metal routings 480, 485. That is to say, polysilicon routing structures 425 below MET 1 layer 460 laterally extend over the trenches 410 and 410′. During manufacturing the polysilicon routing structures 425 may be formed in the same process step as the polysilicon structures 470, 475 within the integrated circuit regions 435 and 440 circumscribed by the respective trenches 410, 410′. As can be seen from FIG. 4, the right layout according to an embodiment may lead to smaller dimensions of the electrical routing and hence to smaller ICs. Further, more routing flexibility may be provided since the polysilicon routing structures 425 provide an additional routing layer beside MET 1 layer 460. This may be particularly beneficial for cost driven ICs comprising at most two metal layers above the polysilicon routing structure 425, for example one signal metal layer and one top power metal layer.

To summarize, some embodiments described in the present disclosure relate to polysilicon routing over trench block(s) using LOCOS for electrical insulation and adequate breakdown voltages between the polysilicon and the trench. Without LOCOS in the upper trench portions polysilicon routing would not be feasible, in particular for power ICs. Embodiments may be particularly useful for cost driven technologies using only a small number of metal layers, for example, at most two (metal 1 and top metal).

The description and drawings merely illustrate the principles of the disclosure. It will thus be appreciated that those skilled in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering the art, and are to be construed as being without limitation to such specifically recited examples and conditions. Moreover, all statements herein reciting principles, aspects, and embodiments of the disclosure, as well as specific examples thereof, are intended to encompass equivalents thereof.

Furthermore, the following claims are hereby incorporated into the detailed description, where each claim may stand on its own as a separate example embodiment. While each claim may stand on its own as a separate example embodiment, it is to be noted that - although a dependent claim may refer in the claims to a specific combination with one or more other claims—other example embodiments may also include a combination of the dependent claim with the subject matter of each other dependent or independent claim. Such combinations are proposed herein unless it is stated that a specific combination is not intended. Furthermore, it is intended to include also features of a claim to any other independent claim even if this claim is not directly made dependent to the independent claim.

It is further to be noted that methods disclosed in the specification or in the claims may be implemented by a device having means for performing each of the respective acts of these methods.

Further, it is to be understood that the disclosure of multiple acts or functions disclosed in the specification or claims may not be construed as to be within the specific order. Therefore, the disclosure of multiple acts or functions will not limit these to a particular order unless such acts or functions are not interchangeable for technical reasons. Furthermore, in some embodiments a single act may include or may be broken into multiple sub acts. Such sub acts may be included and part of the disclosure of this single act unless explicitly excluded.

What is claimed is:

1. A semiconductor device, comprising:
a semiconductor substrate;
a trench extending into the semiconductor substrate, wherein the trench is partly filled with an electrically conductive structure insulated from the semiconductor substrate;
a polysilicon or amorphous silicon routing structure laterally bridging the trench; and
an insulation layer between the trench and the routing structure.

2. The semiconductor device of claim 1, wherein the trench surrounds a first integrated circuit region comprising one or more integrated circuit components, and wherein the routing structure electrically connects at least one integrated circuit component of the first integrated circuit region to at least one integrated circuit component of a second integrated circuit region outside the trench and the first integrated circuit region.

3. The semiconductor device of claim 2, wherein the first integrated circuit region comprises a region of the semiconductor substrate forming an insulated well around the one or more integrated circuit components.

4. The semiconductor device of claim 2, wherein the second integrated circuit region comprises a cell array of a semiconductor power device, the cell array comprising a plurality of transistor cells.

5. The semiconductor device of claim 4, wherein the at least one integrated circuit component of the first integrated circuit region is configured to control at least one gate terminal of a transistor cell of the cell array.

6. The semiconductor device of claim 1, wherein the trench's electrically conductive structure comprises a field plate.

7. The semiconductor device of claim 4, wherein the semiconductor power device is a Double-Diffused MOS, DMOS, device.

8. The semiconductor device of claim 1, wherein the insulation layer has a breakdown voltage of at least 5 Volts between the trench's electrically conductive structure and the routing structure.

9. The semiconductor device of claim 1, wherein the insulation layer has a thickness of at least 30 nm between the trench's electrically conductive structure and the routing structure.

10. The semiconductor device of claim 1, wherein the trench's electrically conductive structure comprises polysilicon, amorphous silicon or tungsten.

11. The semiconductor device of claim 1, wherein the semiconductor device contains at most two metal layers.

12. A method for manufacturing a semiconductor device, comprising:
forming a trench extending into a semiconductor substrate;
partly filling the trench with an electrically conductive structure and insulating the electrically conductive structure from the semiconductor substrate;
forming an insulation layer covering the trench's electrically conductive structure; and
forming, on the insulation layer, a polysilicon or amorphous silicon routing structure laterally extending over the trench.

13. The method of claim 12, further comprising:
forming the trench to surround a first region of the semiconductor substrate;
forming one or more first integrated circuit components into the first region;
forming one or more second integrated circuit components into a second region on an opposite side of the trench; and
forming the routing structure to electrically connect at least one of the first integrated circuit components to at least one of the second integrated circuit components.

14. The method of claim 13, wherein the process of forming the trench surrounding the first region comprises forming at least one further trench in the second region of the semiconductor substrate.

15. The method of claim 13, wherein the process of forming the routing structure laterally extending over the trench comprises forming at least one further polysilicon structure within the first or the second region of the semiconductor substrate.

16. The method of claim 13, wherein forming the one or more second integrated circuit components in the second region comprises forming a cell array of a semiconductor power device.

17. The method of claim 16, wherein forming the one or more first integrated circuit components in the first region comprises forming a control logic circuit for the cell array.

18. The method of claim 12, wherein forming the insulation layer comprises locally oxidizing the electrically conductive structure in an upper portion of the trench.

19. The method of claim 12 wherein forming the trench comprises forming the electrically conductive structure using polysilicon, amorphous silicon or tungsten.

20. The method of claim 12, further comprising:
forming at most two metal layers above the routing structure.
